(19) United States
(12) Patent Application Publication
(10) Pub. No.: US 2008/0040646 A1
(43) Pub. Date: Feb. 14, 2008

(54) RAID ENVIRONMENT INCORPORATING HARDWARE-BASED FINITE FIELD MULTIPLIER FOR ON-THE-FLY XOR

(75) Inventors: Carl Edward Forhan, Rochester, MN (US); Robert Edward Galbraith, Rochester, MN (US); Adrian Cuenin Gerhard, Rochester, MN (US)

Correspondence Address: WOOD, HERRON & EVANS, L.L.P. (IBM), 2700 CAREW TOWER, 441 VINE STREET, CINCINNATI, OH, 45202, US

(73) Assignee: INTERNATIONAL BUSINESS MACHINES CORPORATION, Armonk, NY (US)

(21) Appl. No.: 11/873,085

(22) Filed: Oct. 16, 2007

Related U.S. Application Data
(62) Division of application No. 10/994,099, filed on Nov. 19, 2004.

(51) Int. Cl. G11C 29/42

(52) U.S. Cl. 714/770; 714/E11.03

(57) ABSTRACT

A hardware-based finite field multiplier is used to scale incoming data from a disk drive and XOR the scaled data with the contents of a working buffer when performing resync, rebuild and other exposed mode read operations in a RAID or other disk array environment. As a result, RAID designs relying on parity stripe equations incorporating one or more scaling coefficients are able to overlap read operations to multiple drives and thereby increase parallelism, reduce the number of required buffers, and increase performance.

### CROSS-REFERENCE TO RELATED APPLICATIONS

This application is a divisional of U.S. patent application Ser. No. 10/994,099 filed on Nov. 19, 2004 by Carl Edward Forhan, Robert Edward Galbraith and Adrian Cuenin Gerhard. Furthermore, this application is related to three other divisional applications filed on even date herewith, namely, application Ser. No. ______ (ROC920040176US3), application Ser. No. ______ (ROC920040176US4), and application Ser. No. ______ (ROC920040176US5), as well as to U.S. application Ser. No. 10/994,088, entitled “METHOD AND SYSTEM FOR ENHANCED ERROR IDENTIFICATION WITH DISK ARRAY PARITY CHECKING”, Ser. No. 10/994,086, entitled “METHOD AND SYSTEM FOR IMPROVED BUFFER UTILIZATION FOR DISK ARRAY PARITY UPDATES”, Ser. No. 10/994,098, entitled “METHOD AND SYSTEM FOR INCREASING PARALLELISM OF DISK ACCESSES WHEN RESTORING DATA IN A DISK ARRAY SYSTEM”, and Ser. No. 10/994,097, entitled “METHOD AND SYSTEM FOR RECOVERING FROM ABNORMAL INTERRUPTION OF A PARITY UPDATE OPERATION IN A DISK ARRAY SYSTEM”, all filed on Nov. 19, 2004 by Carl Edward Forhan et al., and to U.S. application Ser. No. 11/867,407 filed on Oct. 4, 2007 by Carl Edward Forhan et al., a divisional application of the above-listed U.S. application Ser. No. 10/994,086. Each of these applications is incorporated by reference herein in its entirety.

### FIELD OF THE INVENTION

The present invention relates to data protection methods for data storage and, more particularly, to systems implementing RAID-6 data protection and recovery strategies.

### BACKGROUND OF THE INVENTION

RAID stands for Redundant Array of Independent Disks and is a taxonomy of redundant disk array storage schemes which define a number of ways of configuring and using multiple computer disk drives to achieve varying levels of availability, performance, capacity and cost while appearing to the software application as a single large capacity drive. Typical RAID storage subsystems can be implemented in either hardware or software. In the former instance, the RAID algorithms are packaged into separate controller hardware coupled to the computer input/output (“I/O”) bus and, although adding little or no central processing unit (“CPU”) overhead, the additional hardware required nevertheless adds to the overall system cost. On the other hand, software implementations incorporate the RAID algorithms into system software executed by the main processor together with the operating system, obviating the need and cost of a separate hardware controller, yet adding to CPU overhead.

Various RAID levels have been defined from RAID-0 to RAID-6, each offering tradeoffs in the previously mentioned factors. RAID-0 is nothing more than traditional striping in which user data is broken into chunks which are stored onto the stripe set by being spread across multiple disks with no data redundancy. RAID-1 is equivalent to conventional “shadowing” or “mirroring” techniques and is the simplest method of achieving data redundancy by having, for each disk, another containing the same data and writing to both disks simultaneously. The combination of RAID-0 and RAID-1 is typically referred to as RAID-0+1 and is implemented by striping shadow sets resulting in the relative performance advantages of both RAID levels. RAID-2, which utilizes Hamming Code written across the members of the RAID set is not now considered to be of significant importance.

In RAID-3, data is striped across a set of disks with the addition of a separate dedicated drive to hold parity data. The parity data is calculated dynamically as user data is written to the other disks to allow reconstruction of the original user data if a drive fails without requiring replication of the data bit-for-bit. Error detection and correction codes (“ECC”) such as Exclusive-OR (“XOR”) or more sophisticated Reed-Solomon techniques may be used to perform the necessary mathematical calculations on the binary data to produce the parity information in RAID-3 and higher level implementations. While parity allows the reconstruction of the user data in the event of a drive failure, the speed of such reconstruction is a function of system workload and the particular algorithm used.

As with RAID-3, the RAID scheme known as RAID-4 consists of N data disks and one parity disk wherein the parity disk sectors contain the bitwise XOR of the corresponding sectors on each data disk. This allows the contents of the data in the RAID set to survive the failure of any one disk. RAID-5 is a modification of RAID-4 which stripes the parity across all of the disks in the array in order to statistically equalize the load on the disks.

The designation of RAID-6 has been used colloquially to describe RAID schemes that can withstand the failure of two disks without losing data through the use of two parity drives (commonly referred to as the “P” and “Q” drives) for redundancy and sophisticated ECC techniques. Although the term “parity” is used to describe the codes used in RAID-6 technologies, the codes are more correctly a type of ECC code rather than simply a parity code. Data and ECC information are striped across all members of the RAID set and write performance is generally lower than with RAID-5 because three separate drives must each be accessed twice during writes. However, the principles of RAID-6 may be used to recover a number of drive failures depending on the number of “parity” drives that are used.

Some RAID-6 implementations are based upon Reed-Solomon algorithms, which depend on Galois Field arithmetic. A complete explanation of Galois Field arithmetic and the mathematics behind RAID-6 can be found in a variety of sources and, therefore, only a brief overview is provided below as background. The Galois Field arithmetic used in these RAID-6 implementations takes place in GF(2^{N}). This is the field of polynomials with coefficients in GF(2), modulo some generator polynomial of degree N. All the polynomials in this field are of degree N−1 or less, and their coefficients are all either 0 or 1, which means they can be represented by a vector of N coefficients all in {0,1}; that is, these polynomials “look” just like N-bit binary numbers. Polynomial addition in this Field is simply N-bit XOR, which has the property that every element of the Field is its own additive inverse, so addition and subtraction are the same operation. Polynomial multiplication in this Field, however, can be performed with table lookup techniques based upon logarithms or with simple combinational logic.

Each RAID-6 check code (i.e., P and Q) expresses an invariant relationship, or equation, between the data on the data disks of the RAID-6 array and the data on one or both of the check disks. If there are C check codes and a set of F disks fail, F≦C, the failed disks can be reconstructed by selecting F of these equations and solving them simultaneously in GF(2^{N}) for the F missing variables. In the RAID-6 systems implemented or contemplated today there are only 2 check disks--check disk P, and check disk Q. It is worth noting that the check disks P and Q change for each stripe of data and parity across the array such that parity data is not written to a dedicated disk but is, instead, striped across all the disks.

Even though RAID-6 has been implemented with varying degrees of success in different ways in different systems, there remains an ongoing need to improve the efficiency and costs of providing RAID-6 protection for data storage. The mathematics of implementing RAID-6 involve complicated calculations that are also repetitive. Accordingly, efforts to improve the simplicity of circuitry, the cost of circuitry and the efficiency of the circuitry needed to implement RAID-6 remains a priority today and in the future.

One limitation of existing RAID-6 designs relates to the performance overhead associated with performing resync (where parity data for a data stripe is resynchronized with the current data), rebuild (where data from a faulty drive is regenerated based upon the parity data) or other exposed mode operations such as exposed mode reads. With other RAID designs, e.g. RAID-5 designs, resyncing parity or rebuilding data simply requires all of the data in a parity stripe to be read in and XOR'ed together. Given that XOR operations are associative in nature, and are thus not dependent upon order, some conventional RAID-5 designs have been able to incorporate “on the fly” XOR operations to improve performance and reduce the amount of buffering required.

In particular, RAID designs incorporating “on the fly” XOR operations issue read requests to the relevant drives in a RAID array, and then as the requested data is returned by each drive, the data is read directly into a hardware-based XOR engine and XOR'ed with the contents of a working buffer. Once all drives have returned the requested data, the working buffer contains the result of the XOR operation. Of note, given the associative nature of the XOR operations, the fact that the precise order in which each drive returns its data is irrelevant. As a result, the drives are able to process the read requests in parallel, and only a single working buffer is required for the operation.

In contrast, with RAID-6 designs, the equations utilized in connection with resyncs and rebuilds (referred to herein as “parity stripe equations”) are not simple XOR operations. Rather, each parity stripe equation typically includes a number of scaling coefficients that scale the respective data read from each drive, which requires that many or all of the data values read from the drives in a RAID-6 design be scaled, or multiplied, by a constant prior to being XOR'ed with the data from other drives into a final sum of products result buffer.

Due to this scaling requirement, read requests to multiple drives typically can only be overlapped if separate buffers are utilized for each drive. Alternatively, if it is desirable for the number of buffers used to be minimized, then read requests must be serialized to ensure that each incoming data value is scaled by the appropriate constant.

As a result, conventional RAID-6 designs, as well as other disk array environments that rely on parity stripe equations that utilize scaling coefficients, often suffer from reduced performance in connection with resync, rebuild and other exposed mode operations due to a shortage of available buffers and/or reduced parallelism.

### SUMMARY OF THE INVENTION

The invention addresses these and other problems associated with the prior art by utilizing a hardware-based finite field multiplier to scale incoming data from a disk drive and XOR the scaled data with the contents of a working buffer. As a result, RAID and other disk array designs relying on parity stripe equations incorporating one or more scaling coefficients are able to overlap read operations to multiple drives and thereby increase parallelism, reduce the number of required buffers, and increase performance.

One aspect of the present invention relates to a method for performing an exposed mode operation in a disk array environment of the type including a plurality of disk drives. The method includes reading a respective data value from a parity stripe from each of the disk drives, wherein the data values from the parity stripe are related to one another according to a parity stripe equation in which at least a portion of the respective data values are scaled by scaling coefficients. The method also includes scaling at least a portion of the respective data values using at least one hardware-based finite field multiplier to generate a plurality of products, and performing an XOR operation on the plurality of products.

Another aspect of the invention relates to a disk array controller comprising a respective data path between an XOR engine of the disk controller and each of a plurality of disk drives, and a respective finite field multiplier circuit in communication with each data path, where each finite field multiplier circuit includes a first respective input for receiving a data value from the respective data path, a second respective input for receiving a respective constant, and a respective output for transmitting a product of the respective data value and the respective constant to the XOR engine.

Yet another aspect of the invention relates to a circuit arrangement that includes a plurality of data paths that are configured to receive data values from a plurality of disk drives, a plurality of hardware-based finite field multiplier circuits, where each finite field multiplier circuit is in communication with one of the plurality of data paths and configured to receive at a first input a data value from a respective data path, and at a second input a respective constant, and where each finite field multiplier circuit is configured to output a product of the respective data value and the respective constant. The circuit arrangement further includes an XOR engine coupled to each data path and configured to receive the product output by each finite field multiplier circuit.

Still another aspect of the invention relates to a disk array controller and a method that rely on two sets of finite field multiplier circuits. Each finite field multiplier circuit in the first set is connected to a respective one of a plurality of disk drives and is configured to receive a data value from the respective disk drive, multiply the data value by a first respective constant, and provide a first respective product to a first XOR engine. Each finite field multiplier circuit in the second set is likewise connected to a respective one of the disk drives and is configured to receive the data value from the respective disk drive, multiply the data value by a second respective constant, and provide a second respective product to a second XOR engine.

### BRIEF DESCRIPTION OF THE DRAWINGS

FIG. 1 is a block diagram of an exemplary computer system that can implement a RAID storage controller in accordance with the principles of the present invention.

FIG. 2 is a block diagram illustrating the principal components of the RAID controller of FIG. 1.

FIG. 3 illustrates a RAID-5 parity generation circuit that supports on-the-fly XOR operations.

FIG. 4 illustrates a RAID-6 parity generation circuit that includes multiple buffers for each data disk drive.

FIG. 5 illustrates an exemplary RAID-6 parity generation circuitry having respective hardware multipliers in-line with each data disk drive such that XOR operations can be performed on-the-fly in accordance with the principles of the present invention.

FIG. 6 illustrates an exemplary RAID-6 environment in which separate multipliers are in-line with the data disk drives such that both parity calculations can occur concurrently in accordance with the principles of the present invention.

FIG. 7 illustrates an exemplary hardware-implemented finite field multiplier for use in the RAID-6 controller of FIG. 2.

### DETAILED DESCRIPTION

The embodiments discussed hereinafter utilize one or more hardware-based finite field multipliers to scale incoming data from the disk drives of a disk array and XOR the scaled data with the contents of a working buffer. Presented hereinafter are a number of embodiments of a disk array environment implementing finite field multiplication consistent with the invention. However, prior to discussing such embodiments, a brief background on RAID-6 is provided, followed by a description of an exemplary hardware environment within which finite field multiplication consistent with the invention may be implemented.

General RAID-6 Background

The nomenclature used herein to describe RAID-6 storage systems conforms to the most readily accepted standards for this field. In particular, there are N drives of which any two are considered to be the parity drives, P and Q. Using Galois Field arithmetic, two independent equations can be written:
α⁰+d₀+α⁰d₁α⁰+d₂+ . . . +α⁰d_{N-1}=0 (1)
α⁰d₀+α¹d₁+α²d₂+ . . . +α^{N-1}d_{N-1}=0 (2)
where the “+” operator used herein represents an Exclusive-OR (XOR) operation.

In these equations, α^{x} is an element of the finite field and dₓ is data from the x^{th} disk. While the P and Q disk can be any of the N disks for any particular stripe of data, they are often noted as d_{P} and d_{Q}. When data to one of the disks (i.e., d_{X}) is updated, the above two equations resolve to:
Δ=(old d_{X})+(new d_{X}) (3)
(new d_{P})=(old d_{P})+((α^{Q}+α^{X})/(α^{P}+α^{Q}))Δ (4)
(new d_{Q})=(old d_{Q})+((α^{P}+α^{X})/(α^{P}+α^{Q}))Δ (5)

In each of the last two equations the term to the right of the addition sign is a constant multiplied by the change in the data (i.e., Δ). These terms in equations (4) and (5) are often denoted as K₁Δ and K₂Δ, respectively.

In the case of one missing, or unavailable drive, simple XOR'ing can be used to recover the drive's data. For example, if d₁ fails then d₁ can be restored by
d₁=d₀+d₂+d₃+ (6)

In the case of two drives failing, or being “exposed”, the above equations can be used to restore a drive's data. For example, given drives 0 through X and assuming drives A and B have failed, the data for either drive can be restored from the remaining drives. If for example, drive A was to be restored, the above equations reduce to:
d_{A}=((α^{B}+α⁰)/(α^{B}+α^{A}))d₀+(α^{B}+α¹)/(α^{B}+α^{A}))d₁+ . . . +((α^{B}+α^{X})/(α^{B}+α^{A}))dₓ (7)
Exemplary Hardware Environment

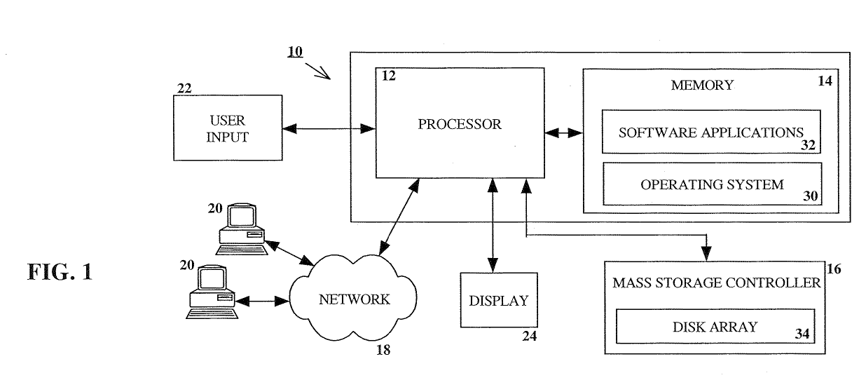

With this general background of RAID-6 in mind, attention can be turned to the drawings, wherein like numbers denote like parts throughout the several views. FIG. 1 illustrates an exemplary computer system in which a RAID-6, or other disk array, may be implemented. For the purposes of the invention, apparatus 10 may represent practically any type of computer, computer system or other programmable electronic device, including a client computer, a server computer, a portable computer, a handheld computer, an embedded controller, etc. Moreover, apparatus 10 may be implemented using one or more networked computers, e.g., in a cluster or other distributed computing system. Apparatus 10 will hereinafter also be referred to as a “computer”, although it should be appreciated the term “apparatus” may also include other suitable programmable electronic devices consistent with the invention.

Computer 10 typically includes at least one processor 12 coupled to a memory 14. Processor 12 may represent one or more processors (e.g., microprocessors), and memory 14 may represent the random access memory (RAM) devices comprising the main storage of computer 10, as well as any supplemental levels of memory, e.g., cache memories, non-volatile or backup memories (e.g., programmable or flash memories), read-only memories, etc. In addition, memory 14 may be considered to include memory storage physically located elsewhere in computer 10, e.g., any cache memory in a processor 12, as well as any storage capacity used as a virtual memory, e.g., as stored on the disk array 34 or on another computer coupled to computer 10 via network 18 (e.g., a client computer 20).

Computer 10 also typically receives a number of inputs and outputs for communicating information externally. For interface with a user or operator, computer 10 typically includes one or more user input devices 22 (e.g., a keyboard, a mouse, a trackball, a joystick, a touchpad, and/or a microphone, among others) and a display 24 (e.g., a CRT monitor, an LCD display panel, and/or a speaker, among others). Otherwise, user input may be received via another computer (e.g., a computer 20) interfaced with computer 10 over network 18, or via a dedicated workstation interface or the like.

For additional storage, computer 10 may also include one or more mass storage devices accessed via a storage controller, or adapter, 16, e.g., removable disk drive, a hard disk drive, a direct access storage device (DASD), an optical drive (e.g., a CD drive, a DVD drive, etc.), and/or a tape drive, among others. Furthermore, computer 10 may include an interface with one or more networks 18 (e.g., a LAN, a WAN, a wireless network, and/or the Internet, among others) to permit the communication of information with other computers coupled to the network. It should be appreciated that computer 10 typically includes suitable analog and/or digital interfaces between processor 12 and each of components 14, 16, 18, 22 and 24 as is well known in the art.

In accordance with the principles of the present invention, the mass storage controller 16 advantageously implements RAID-6 storage protection within an array of disks 34.

Computer 10 operates under the control of an operating system 30, and executes or otherwise relies upon various computer software applications, components, programs, objects, modules, data structures, etc. (e.g., software applications 32). Moreover, various applications, components, programs, objects, modules, etc. may also execute on one or more processors in another computer coupled to computer 10 via a network 18, e.g., in a distributed or client-server computing environment, whereby the processing required to implement the functions of a computer program may be allocated to multiple computers over a network.

In general, the routines executed to implement the embodiments of the invention, whether implemented as part of an operating system or a specific application, component, program, object, module or sequence of instructions, or even a subset thereof, will be referred to herein as “computer program code,” or simply “program code.” Program code typically comprises one or more instructions that are resident at various times in various memory and storage devices in a computer, and that, when read and executed by one or more processors in a computer, cause that computer to perform the steps necessary to execute steps or elements embodying the various aspects of the invention. Moreover, while the invention has and hereinafter will be described in the context of fully functioning computers and computer systems, those skilled in the art will appreciate that the various embodiments of the invention are capable of being distributed as a program product in a variety of forms, and that the invention applies equally regardless of the particular type of computer readable signal bearing media used to actually carry out the distribution. Examples of computer readable signal bearing media include but are not limited to recordable type media such as volatile and non-volatile memory devices, floppy and other removable disks, hard disk drives, magnetic tape, optical disks (e.g., CD-ROM's, DVD's, etc.), among others, and transmission type media such as digital and analog communication links.

In addition, various program code described hereinafter may be identified based upon the application within which it is implemented in a specific embodiment of the invention. However, it should be appreciated that any particular program nomenclature that follows is used merely for convenience, and thus the invention should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, API's, applications, applets, etc.), it should be appreciated that the invention is not limited to the specific organization and allocation of program functionality described herein.

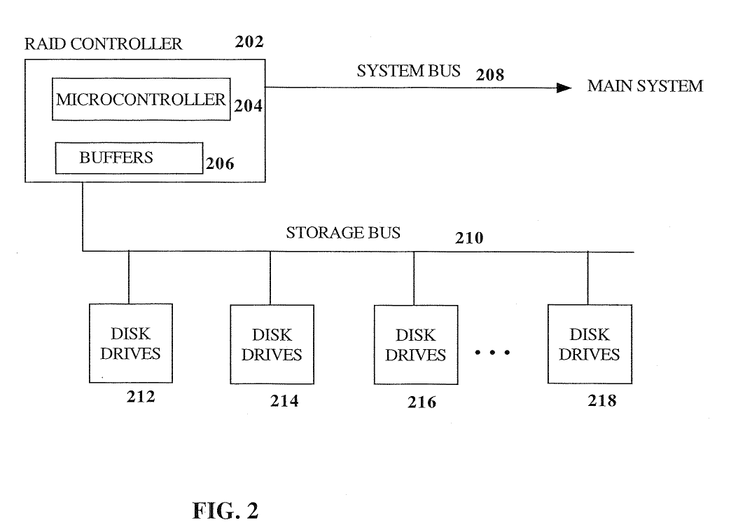

FIG. 2 illustrates a block diagram of the control subsystem of a disk array system, e.g., a RAID-6 compatible system. In particular, the mass storage controller 16 of FIG. 1 is shown in more detail to include a RAID controller 202 that is coupled through a system bus 208 with the processor 12 and through a storage bus 210 to various disk drives 212-218. As known to one of ordinary skill, these buses may be proprietary in nature or conform to industry standards such as SCSI-1, SCSI-2, etc. The RAID controller includes a microcontroller 204 that executes program code that implements the RAID-6 algorithm for data protection, and that is typically resident in memory located in the RAID controller. In particular, data to be stored on the disks 212-218 is used to generate parity data and then broken apart and striped across the disks 212-218. The disk drives 212-218 can be individual disk drives that are directly coupled to the controller 202 through the bus 210 or may include their own disk drive adapters that permit a string a individual disk drives to be connected to the storage bus 210. In other words, a disk drive 212 may be physically implemented as 4 or 8 separate disk drives coupled to a single controller connected to the bus 210. As data is exchanged between the disk drives 212-218 and the RAID controller 202, in either direction, buffers 206 are provided to assist in the data transfers. The utilization of the buffers 206 can sometimes produce a bottle neck in data transfers and the inclusion of numerous buffers may increase cost, complexity and size of the RAID controller 202. Thus, certain embodiments of the present invention relate to provision and utilizing these buffers 206 in an economical and efficient manner.

It will be appreciated that the embodiment illustrated in FIGS. 1 and 2 is merely exemplary in nature. For example, it will be appreciated that the invention may be applicable to other disk array environments where parity stripe equations require data from one or more disks to be scaled by a constant. It will also be appreciated that a disk array environment consistent with the invention may utilize a completely software-implemented control algorithm resident in the main storage of the computer, or that some functions handled via program code in a computer or controller can be implemented in hardware logic circuits, and vice versa. Therefore, the invention should not be limited to the particular embodiments discussed herein.

Hardware-Based Finite Multiplier for On-The-Fly XOR

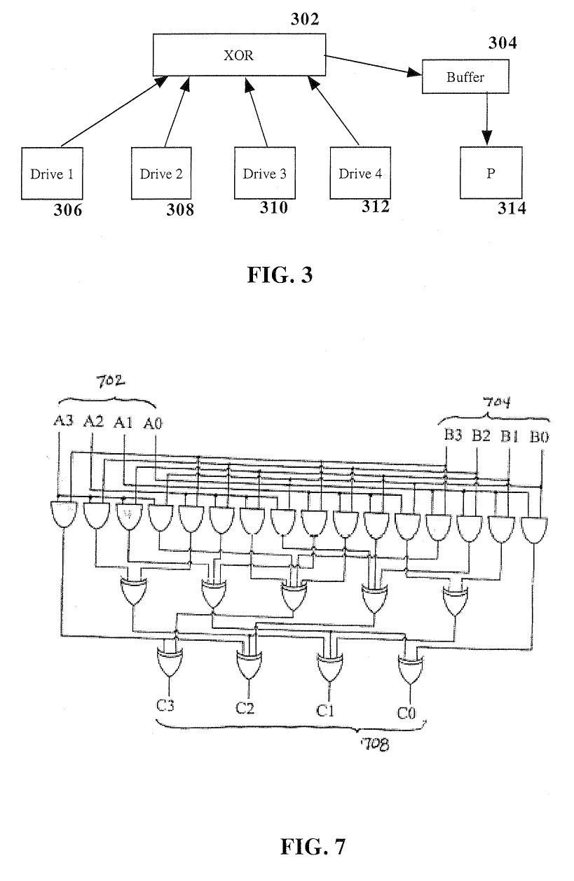

As noted above, in RAID-5 systems, to rebuild data or to resynchronize the parity data requires the data from all the other drives to be read and then XOR'ed together. A block diagram of an on-the-fly XOR engine is depicted in FIG. 3 and is easily implemented on a RAID controller. When performing a resync, the data disks 306-312 are read and XOR'ed together in an XOR engine 302 in order to generate parity data that is written to a buffer 304 and then to the parity drive, P, 314. A rebuilding operation of a data drive would be similar, except that the parity disk and other data disks are all read and XOR'ed together to generate the data to write to the rebuilt disk. When performing an exposed mode read, the data from the missing drive is generated by reading the parity data and other disks' data and performing an XOR operation. Because XOR can be accomplished in any order, the reading of the data from different disks 306-312 can be performed as overlapped, or concurrent, I/O operations and utilize a single XOR engine 302 and buffer 304. If the XOR engine 302 acts as both the input and destination buffer, then the separate buffer 304 may even be omitted because the XOR engine 302 simply XOR's an incoming data value with the current contents of its internal buffer.

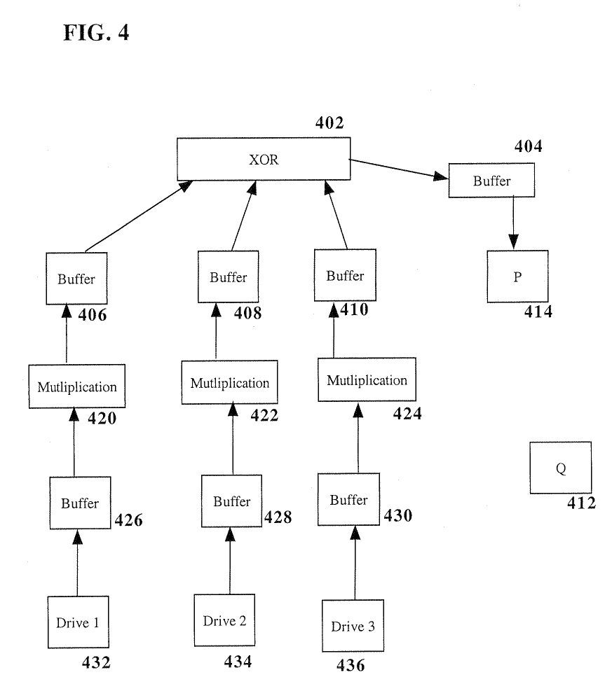

As also noted above, in RAID-6 a multiplication or scaling operations is required on the data that is read from each disk drive. Accordingly, a buffer and XOR arrangement similar to that of FIG. 4 is typically used. The data from different drives 432-436 is read into separate buffers 426-430, multiplied by an appropriate scaling coefficient in a multiplication step 420-424 typically performed by the software micro-code of the RAID controller, written to additional buffers 406-410. The contents of buffers 406-410 are then XOR'ed together in XOR engine 402. The parity data P is then written through a buffer 404 to the parity disk 414. A rebuilding operation of a data drive would be similar, except that a parity disk P or Q and other data disks are all read, multiplied and XOR'ed together to generate the data to write to the rebuilt disk.

For an array of N disks, data typically must be read from N−2 different disks to perform a resync, rebuild, or exposed mode read. In order for these read I/O operations to be overlapped, N−2 buffers are needed. If less than N−2 buffers are available, then some of the read I/O operations will have to wait until other read operations finish. For any rebuild, resync, or exposed mode read, only N−2 disks are needed so one disk, such as the Q disk 412 may not be utilized in the arrangement of FIG. 4.

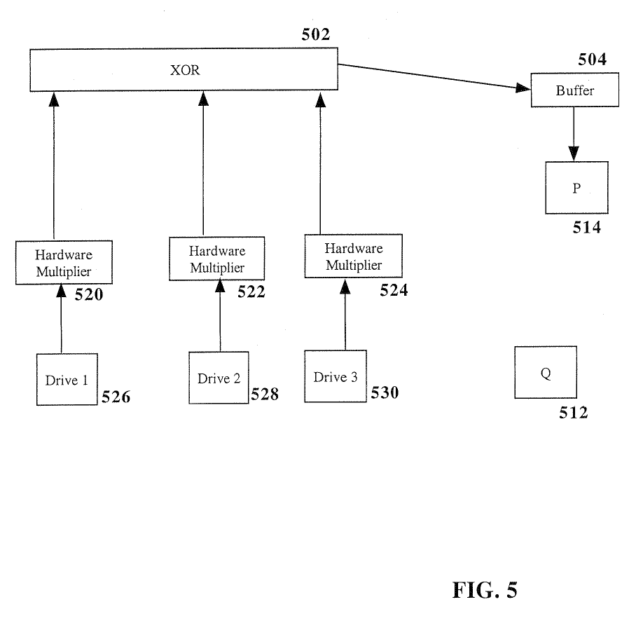

Embodiments of the present invention include a finite field multiplier implemented as hardware inserted within the data path as data is retrieved from a disk by a RAID controller. FIG. 5, in particular, illustrates a schematic diagram of such an arrangement within the controller, shown coupled to an array including drives 526-530 and P and Q parity drives 514, 512. As the data is read from each drive 526-530 into the controller, a multiplier 520-524 multiplies each byte by a constant previously determined by software microcode of the RAID controller. This multiplier logic may be repeated n times in order to handle that many different drives, or alternatively, a single multiplier may be used for all drives. The result of each multiplier may then be fed into an on-the-fly XOR engine 502 similar to that described with respect to FIG. 3. Thus, the results of the different multipliers 520-524 are XOR'ed together in the engine 502 and written to the parity drive P 514 through a buffer 504, in much the same manner as a RAID-5 implementation such as shown in FIG. 3.

Consequently, as the data is read from a drive, it is multiplied by a constant without utilizing an intermediate buffer. These products are then fed into an XOR engine irrespective of the order in which they were read. Accordingly, the I/O read operations of the different disks can be performed in an overlapped or concurrent manner. The specific value of the constant multiplier for each disk's data is determined according to the relevant parity stripe equation, e.g., equation (7) above. These constants are predetermined by software microcode of the RAID controller based on the type of exposed mode operation being performed.

One exemplary hardware-based implementation of a finite field multiplier is depicted in FIG. 7, which uses basic logic gates electrically coupled to one another to perform the multiplication step. This particular multiplier operates on word sizes of 4 bits within a Galois Field having a primitive polynomial of x⁴+x+1. The data from a disk is read in as inputs A₀-A₃ 702 and the respective constant is fed into the multiplier as inputs B₀-B₃ 704. The resulting product is output as C₀-C₃ 708. One of ordinary skill will recognize that the multiplier of FIG. 7 is exemplary in nature and that different primitive polynomials and word sizes may be used without departing from the scope of the present invention. Other hardware implementations may be utilized as well. For example, a VHDL implementation of an 8-bit multiplier is provided below in Table I, in which the primitive polynomial is x⁸+x⁴+x³+x+1. Such a multiplier may be realized in a variety of hardware embodiments.

TABLE I
8-bit Multiplier

architecture rs8 of mult is

signal terms : std_ulogic_vector (0 to 63);
signal terms2 : std_ulogic_vector (0 - 15);

begin

fillterms:for i in 0 to 63 generate

terms(i) <= (opr1(i/8) and opr2(i − ((i/8)*8)));

end generate fillterms;
terms2(14) <= terms (0);
terms2(13) <= terms(1) XOR terms (8);
terms2(12) <= terms (2) XOR terms(9) XOR terms (16);
terms2(11) <- terms(3) XOR terms(10) XOR terms(17) XOR terms (24;)
terms2(10) <= terms(4) XOR terms(11) XOR terms(18) XOR terms (25) XOR terms(32);
terms2(9) <= terms(5) XOR terms(12) XOR terms(19) XOR terms (26) XOR terms (33)

XOR terms (40;)

terms2(8) <= terms(6) XOR terms(13) XOR terms(20) XOR terms (27) XOR terms (34)

XOR terms (41) XOR terms(48);

terms2(7) <= terms(7) XOR terms(43) XOR terms(21) XOR terms (28) XOR terms (35)

XOR terms (42) XOR terms(49) XOR terms(56);

terms2(6) <= terms(15) XOR terms(22) XOR terms(29) XOR terms (36) XOR terms (43)

XOR terms (50) XOR terms(57);

terms2(5) <= terms(23) XOR terms(30) XOR terms (37) XOR terms(44) XOR terms(51)

XOR terms (58);

terms2(4) <= terms( 31) XOR terms(38) XOR terms(45) XOR terms(52) XOR terms(59);
terms2(3) <= terms(39) XOR terms(46) XOR terms(53) XOR terms(60);
terms2(2) <= terms(47) XOR terms(54) XOR terms(61);
terms2(1) <= terms(55) XOR terms(62);
terms2(0) <= terms(62);
prod(0) <= terms2(7) XOR terms2(11) XOR terms2(12) XOR terms2(13;)
prod(1) <= terms2(6) XOR terms2(10) XOR terms2(11) XOR terms2(12;)
prod(2) <= terms2(5) XOR terms2(9) XOR terms2(10) XOR terms2(11);
prod(3) <= terms2(4) XOR terms2(8) XOR terms2(9) XOR terms2(10) XOR terms2(14);
prod(4) <= terms2(3) XOR terms2(8) XOR terms2(9) XOR terms2(11) XOR terms2(12);
prod(5) <= terms2(2) XOR terms2(8) XOR terms2(10) XOR terms2(12 XOR terms2(13);)
prod(6) <= terms2(1) XOR terms2(9) XOR terms2(13) XOR terms2(14);
prod(7) <= terms2(0) XOR terms2(8) XOR terms2(12) XOR terms2(13) XOR terms2(14);

end rs8

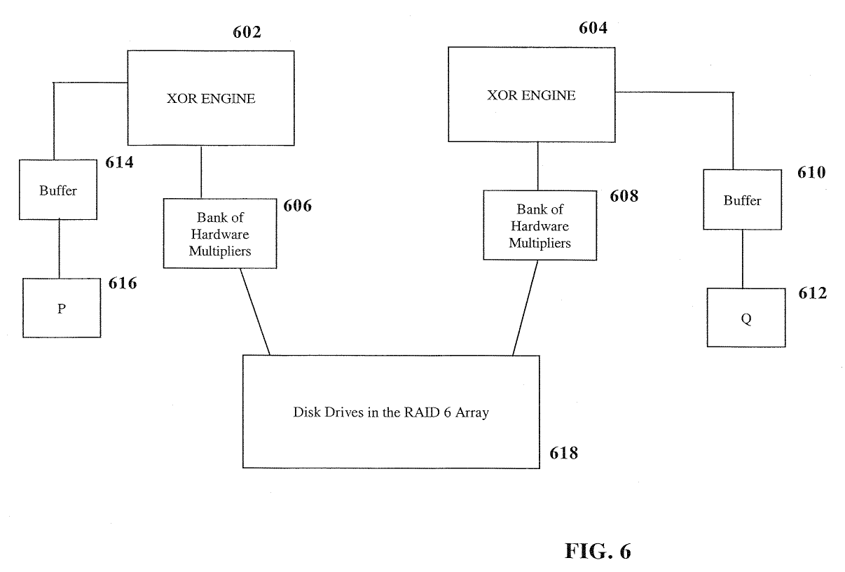

The in-line hardware multiplier circuitry described above may also be arranged in such a manner as to permit concurrent resynchronization of both parity codes, P and Q; or allow two exposed disks to be rebuilt. FIG. 6 illustrates such an arrangement. In this exemplary configuration, data is read from each of the disk 618 and, respectively, passes through two different banks of hardware multipliers 606, 608. The respective products from these respective multipliers are then XOR'ed together in respective XOR engines 602, 604 to generate the data to write back to the other two disks of the array, disk P 616 and disk Q 612 through respective buffers 614, 610. Accordingly, both sets of parity may be resynced with only two buffers and one set of overlapped reads or, in the case of rebuilding, two exposed drives may be rebuilt in the same time it takes to rebuild one drive.

Thus, embodiments of the present invention provide a method and system that utilize hardware-based finite field multipliers in the data path of the disk drives in order to perform on-the-fly XOR calculations with a reduced number of buffers. Various modifications may be made to the illustrated embodiments without departing from the spirit and scope of the invention. Therefore, the invention lies in the claims hereinafter appended.

What is claimed is:

1. A method for performing an exposed mode operation in a disk array environment of the type including a plurality of disk drives, the method comprising the steps of:
reading a respective data value from a parity stripe from each of the disk drives, wherein the data values from the parity stripe are related to one another according to a parity stripe equation in which at least a portion of the respective data values are scaled by scaling coefficients;
scaling at least a portion of the respective data values using at least one hardware-based finite field multiplier to generate a plurality of products; and
performing an XOR operation on the plurality of products.

2. The method of claim 1, wherein the finite field multiplier consists essentially of a plurality of electrically coupled logic gates.

3. The method of claim 1, wherein reading the respective data value from the parity stripe from each of the disk drives includes issuing a plurality of overlapping read requests such that the read requests are processed concurrently by the plurality of disk drives.

4. The method of claim 1, wherein the exposed mode operation comprises one of a rebuild operation, a resynchronization operation, and an exposed mode read operation.

5. The method of claim 1, wherein performing the XOR operation comprises performing an on-the-fly XOR operation.

6. The method of claim 1, further comprising, concurrently with scaling the portion of the respective data values using the hardware-based finite field multiplier to generate the plurality of products, scaling at least a portion of the respective data values using at least one additional hardware-based finite field multiplier to generate a second plurality of products, and performing an XOR operation on the second plurality of products.
